(19) United States
(12) Patent Application Publication
(10) Pub. No.: US 2026/0276708 A1
(43) Pub. Date: Sep. 17, 2026

(54) GLITCH-FREE RESET TESTING SYSTEM

(71) Applicant: STMicroelectronics International N.V., Geneva (CH)

(72) Inventors: Venkata Narayanan Srinivasan, Greater Noida (IN); Balwinder Singh Soni, Faridabad (IN)

(21) Appl. No.: 19/079,857

(22) Filed: Mar. 14, 2025

(51) Int. Cl. G01R 31/3187; H03K 17/22; H03K 19/003; H03K 19/20

(52) U.S. Cl. CPC G01R 31/3187; H03K 17/22; H03K 19/00346; H03K 19/20

(57) ABSTRACT

According to an embodiment, a glitch-free reset testing system for system-on-chip designs includes a hierarchical reset distribution architecture with a reset generation circuit, a reset select logic circuit, and multiple intellectual property (IP) blocks. Each circuit incorporates a one-hot decoder integrated within its scan chain to control reset propagation. The one-hot decoders enable selective activation of reset signals to individual pipeline stages while preventing glitch propagation between stages. A power management controller digital circuit multiplexes analog reset sources with scan reset signals at the primary input stage. The architecture eliminates scan reset multiplexers at each pipeline stage, reducing functional path delays while maintaining full stuck-at-fault coverage. The most significant bit of each one-hot decoder determines the reset domain, allowing resets to be confined to specific circuits.

### TECHNICAL FIELD

The present disclosure generally relates to design for testability (DFT) and, in particular embodiments, to a glitch-free reset testing system.

### BACKGROUND

System-on-chip (SoC) designs incorporate reset mechanisms to control the initialization and operation of different components. A typical SoC reset architecture can include a reset generation circuit that serves as the primary reset controller, a reset selection circuit that determines which intellectual property (IP) blocks receive reset signals, and multiple IP blocks that can be reset independently. The reset generation circuit can receive inputs from analog blocks like power management controllers, monitors, and threshold detectors.

Design for testability (DFT) techniques allow testing of reset functionality through scan chains. Test patterns are shifted into scan chains during scan testing when a scan enable is asserted. The scan chains can capture circuit responses through, for example, clock pulses or reset pulses when scan enable is de-asserted. The captured values are shifted out and compared against expected results.

Reset testing can often involve scanning in specific test patterns and applying reset pulses to verify proper reset behavior. The scan chains load test values during shift mode when a scan enable signal is high. These values remain stable during capture mode when the scan enable signal transitions to a low state.

Power management controllers provide reset sources during normal functional operation. During test mode, scan reset signals can be multiplexed with these functional reset sources to enable testing. The reset signals propagate through multiple pipeline stages within the SoC's reset distribution network to reach various destination flip-flops and IP blocks.

### SUMMARY

Technical advantages are generally achieved by embodiments of this disclosure, which describe a glitch-free reset testing system.

A first aspect relates to a reset testing system, comprising a reset generation circuit including a first one-hot decoder, the reset generation circuit configured to generate and manage reset signals during functional and test operations; a reset select logic circuit coupled to the reset generation circuit and including a second one-hot decoder, the reset select logic circuit configured to route reset signals to different intellectual property (IP) blocks; and a plurality of intellectual property (IP) blocks coupled to the reset select logic circuit, each IP block including a third one-hot decoder and configured to perform dedicated processing operations within a system-on-chip, wherein each of the first one-hot decoder, the second one-hot decoder, and the third one-hot decoder is configured to control reset distribution within their respective circuits during test mode to prevent glitch propagation by activating reset in only one stage at a time.

A second aspect relates to a reset generation logic circuit, comprising a functional combinational logic circuit configured to process reset signals during functional operation; a first OR gate having a first input coupled to receive a one-hot decoder reset signal and a second input coupled to receive a scan reset signal; an AND gate having a first input coupled to an output of the first OR gate and a second input coupled to receive a scan mode control signal; and a second OR gate having a first input coupled to an output of the AND gate and a second input coupled to an output of the functional combinational logic circuit, the second OR gate configured to selectively output either the functional reset signal or the test reset signal based on the scan mode control signal, wherein the one-hot decoder reset signal is derived from a one-hot decoder that controls reset distribution to prevent glitch propagation by activating reset in only one stage at a time.

A third aspect relates to a method for design for testability (DFT) in a system-on-chip (SoC), the method comprising loading test values into one-hot decoders within a reset generation circuit, a reset select logic circuit, and a plurality of intellectual property (IP) blocks during a shift phase in response to a scan enable signal being at a first logic level, wherein the reset generation circuit is configured to generate reset signals, the reset select logic circuit is configured to route reset signals, and each IP block is configured to perform dedicated processing operations within the system-on-chip; transitioning the scan enable signal to a second logic level to begin a capture phase; transitioning a scan reset signal from the first logic level to the second logic level during the capture phase; and controlling reset distribution based on values in the one-hot decoders to prevent glitch propagation by activating reset in only one stage at a time.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a block diagram of an embodiment reset generation logic circuit;

FIGS. 2 and 3 are exemplary shift and capture waveforms for automatic test pattern generation (ATPG) operations in the reset generation logic circuit;

FIG. 4 is a schematic of an embodiment circuit showing a problematic reset path configuration in a scan chain that can lead to unwanted glitches during test operations;

FIG. 5 is a schematic of an embodiment reset generation logic circuit;

FIG. 6 is a block diagram of an embodiment reset generation circuit;

FIG. 7 is a block diagram of an embodiment reset select logic circuit;

FIG. 8 is a block diagram of an embodiment IP block;

FIG. 9 is a flowchart of an embodiment method for controlling reset distribution in a system-on-chip (SoC); and

FIG. 10 is a flowchart of an embodiment method for design for testability (DFT) in a system-on-chip (SoC).

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of system-on-chip reset testing and verification, it should also be appreciated that they may also apply to general integrated circuit testing and debugging. In particular, aspects of this disclosure may similarly apply to, for example, power management control systems, boot sequence verification, protocol interface testing, and multi-stage pipeline testing architectures.

Aspects of the disclosure provide techniques for testing reset logic in system-on-chip (SoC) designs through a hierarchical reset distribution architecture. In embodiments, the architecture incorporates a reset generation circuit, a reset selection circuit, and multiple intellectual property (IP) blocks, each containing a one-hot decoder integrated within their scan chains. The one-hot decoders enable selective control of reset propagation to individual pipeline stages while preventing glitch propagation between stages during scan testing.

In embodiments, a power management controller digital (PMCD) circuit multiplexes analog reset sources like power-on-reset and monitor outputs with scan reset signals at the primary input stage. The scan chains load test patterns during shift mode when scan enable is asserted. During capture mode, when scan enable transitions are low, the one-hot decoder values remain stable, allowing controlled reset activation of specific pipeline stages. The most significant bit of the reset generation circuit's decoder determines the reset domain (e.g., when set to ‘0’, resets occur only within the reset generation circuit; when set to ‘1’, resets can propagate to the selection circuit and IP blocks based on additional control bits).

The architecture eliminates scan reset multiplexers at each pipeline stage, which traditionally prevents glitch propagation. Instead, glitch-free operation is achieved by activating resets in only one pipeline stage at a time through the one-hot decoders. This reduces functional path delays by removing AND gate delays from reset paths while maintaining full stuck-at-fault coverage. The scan reset signal can double as the internal reset control signal, eliminating the need for additional control signals to reduce test parallelism.

The one-hot decoders can integrate naturally into existing scan chains without requiring dedicated observation flip-flops or conversion of non-resettable flip-flops to resettable versions. This maintains the original test time while achieving complete reset path coverage. The reduced multiplexer count and elimination of observation logic results in a smaller area overhead compared to conventional solutions that require additional multiplexers, observation flip-flops, or flip-flop modifications.

The hierarchical nature of the architecture allows independent reset control of the reset generation circuit, selection circuit, and IP blocks through their respective one-hot decoders. This modular approach simplifies debugging and provides flexibility in testing different reset domains while maintaining signal integrity throughout the reset distribution network. These and additional details are further discussed below.

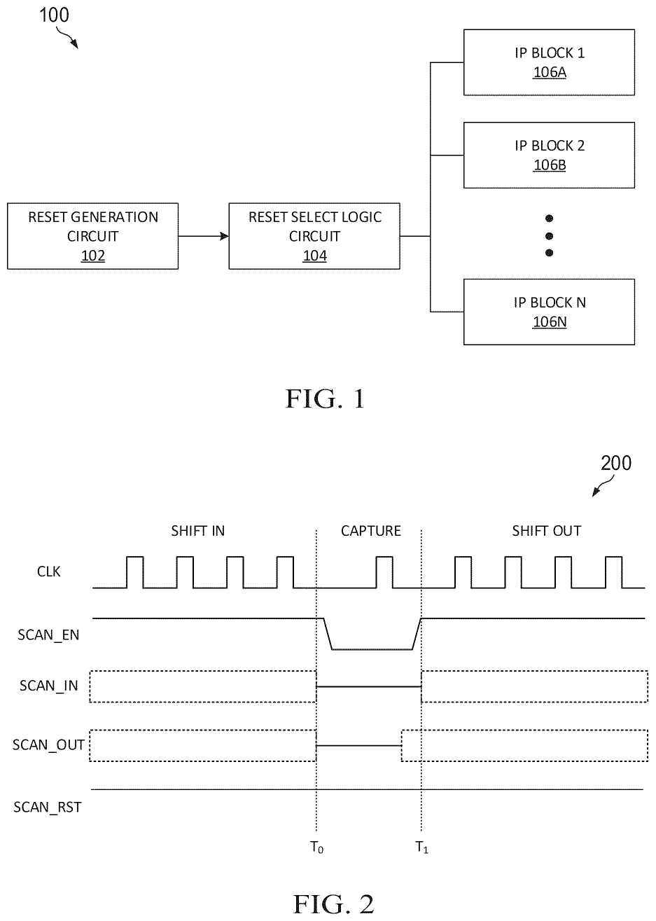

FIG. 1 illustrates a block diagram of an embodiment reset generation logic circuit 100, which can form a reset architecture for an integrated circuit combining multiple functional circuits (i.e., blocks) on a single system-on-chip (SoC). The reset generation logic circuit 100 includes a reset generation circuit 102, a reset select logic circuit 104, and multiple intellectual property (IP) blocks 106, which may (or may not) be arranged as shown. The circuit may include additional components not shown.

The reset generation circuit 102 is the primary reset controller that generates and manages reset signals during functional and test operations. This circuit interfaces with analog blocks like power management controllers and incorporates one-hot decoders within its scan chain for controlling internal reset stages.

The reset select logic circuit 104 is a distribution hub that routes reset signals to different IP blocks. It contains selection logic and one-hot decoders in its scan chain to control which reset signals propagate to which IP blocks.

The IP blocks 106 represent various functional circuits within the SoC, such as processors, memory controllers, or interface protocols. In embodiments, each IP block 106A-N contains a reset staging logic to manage internal reset distribution.

In the reset generation logic circuit 100, the reset generation circuit 102 produces reset signals that feed into the reset select logic circuit 104. The reset select logic circuit 104 determines which IP blocks (106) receive these reset signals based on decoder values and control signals. This hierarchical arrangement allows for selective reset testing of individual stages within the reset generation circuit 102, the reset select logic circuit 104, or any IP block 106 while preventing unwanted glitch propagation between stages.

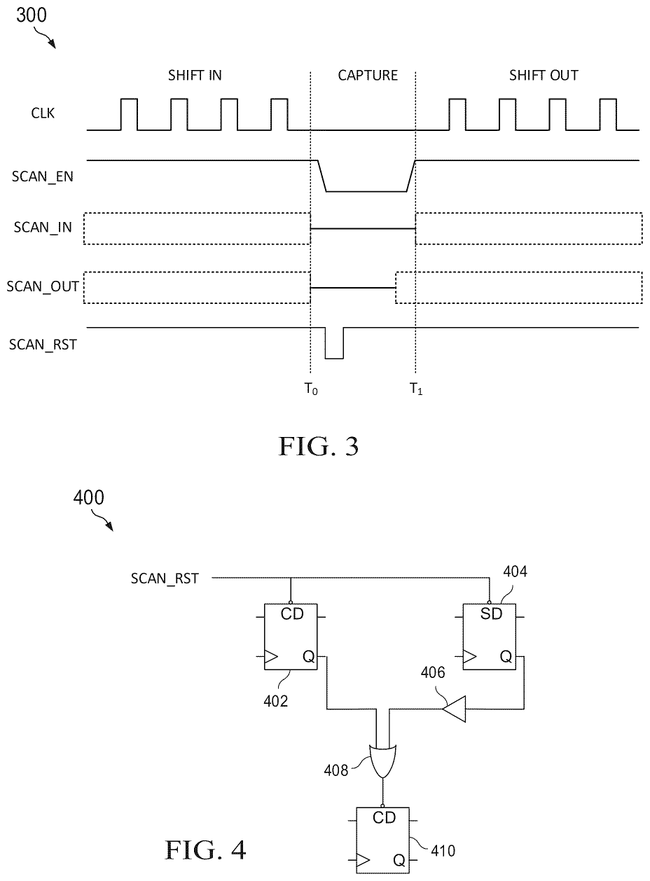

FIG. 2 and FIG. 3 illustrate exemplary shift and capture waveforms 200 and 300, respectively, for automatic test pattern generation (ATPG) operations in the reset generation logic circuit 100. The waveforms show the timing relationships between the scan chain clock (CLK) signal, the scan enable (SCAN_EN) signal, the scan in (SCAN_IN) signal, the scan out (SCAN_OUT) signal, and the scan reset (SCAN_RST) signal.

Each waveform can be divided into three distinct phases: shift-in (i.e., before time T₀), capture (i.e., between times T₀ and T₁), and shift-out (i.e., after time T₁). During the shift-in phase, the scan enable signal remains at logic high while test patterns are serially shifted into the scan chains through the scan-in signal on each rising edge of the scan chain clock signal. The data values corresponding to the scan-in and scan-out signals may vary based on the specific test patterns.

At time T₀, the capture phase begins when the scan enable signal transitions to logic low. FIG. 2 shows a clock-based capture operation where circuit responses are captured on the rising edge of the scan chain clock signal times T₀ and T₁ while the scan reset signal remains inactive (logic high). This represents the standard scan testing methodology.

FIG. 3 demonstrates an alternative capture mechanism where the scan reset signal pulses low between times T₀ and T₁. In this case, the circuit responses are captured based on the reset event rather than the clock edge. This reset-based capture is advantageous for testing reset functionality throughout the reset distribution network.

After time T₁, both waveforms enter the shift-out phase where the scan enable signal returns to logic high. The captured responses are then shifted out through the scan-out signal while new test patterns are simultaneously shifted in through the scan-in signal, beginning the next test cycle.

In embodiments, reset generation logic circuit 100 supports clock-triggered and reset-triggered capture operations, providing flexibility in testing different aspects of the reset distribution network. The control of the scan enable and reset signal transitions relative to the scan chain clock signal edges ensure reliable capture of circuit responses while preventing unwanted interactions between test signals that could corrupt test results.

FIG. 4 illustrates a schematic of an embodiment circuit 400 showing a problematic reset path configuration in a scan chain that can lead to unwanted glitches during test operations. The circuit includes a first flip-flop 402, a second flip-flop 404, a third flip-flop 410, and associated logic components demonstrating how timing delays in internal reset paths can cause reset testing issues.

The first flip-flop 402 has a Clear/Direct (CD) input coupled to the scan reset signal. The second flip-flop 404 has a Set/Direct (SD) input also coupled to the scan reset signal. A buffer 406 is coupled to the output (Q) of the second flip-flop 404. The third flip-flop 410 has a CD input coupled to the output of an OR gate 408. The OR gate 408 receives inputs from the Q output of the first flip-flop 402 and the buffered Q output from the second flip-flop 404.

During scan test mode, at the end of the shift phase, the Q output value is ‘1’ for the first flip-flop 402 and ‘0’ for the second flip-flop 404. When the scan reset signal pulses low after time T₀, the first flip-flop 402 transitions from ‘1’ to ‘0’ (resets), while the second flip-flop 404 transitions from ‘0’ to ‘1’ (sets). Ideally, these transitions would occur simultaneously, maintaining a logic ‘1’ at the OR gate 408 output and preventing an unwanted reset of the third flip-flop 410.

However, buffer 406 delays the ‘0’ to ‘1’ transition of the Q output from the second flip-flop 404. This delay creates a critical timing window where both inputs to the OR gate 408 may be ‘0’—the first input transitions quickly to ‘0’ from the first flip-flop 402, while the second input is still at ‘0’ due to the delayed transition through buffer 406. This momentary condition causes the OR gate output to pulse to ‘0’, creating an unwanted reset pulse (glitch) at the third flip-flop 410′s CD input.

The circuit 400 thus demonstrates how conventional reset path designs can experience glitch issues during scan testing due to timing mismatches between parallel paths. This glitch generation mechanism becomes particularly problematic when achieving complete stuck-at-fault coverage of reset paths in complex SoC designs.

One existing approach for addressing reset path glitches involves adding multiplexers after each combinational logic gate (e.g., the OR gate 408) that feeds into flip-flop reset or set pins. The scan reset signal propagates through these multiplexers while blocking the combinational logic paths during scan mode. The solution also includes XORing all combinational logic outputs and connecting them to the data input of an observation flip-flop or the reset pin of another flip-flop through an additional multiplexer or by converting a non-resettable flip-flop to a resettable flip-flop.

However, this approach has several drawbacks. Coverage loss occurs on the multiplexer inputs connected to the combinational logic since those paths are blocked during scan mode. The additional multiplexers introduce delays on functional reset paths, impacting timing. When using observation flip-flops, their data inputs have hold time requirements and are included in scan chains, increasing test time. The extra XOR logic, observation flip-flops, and converting non-resettable flip-flops to resettable versions also increase circuit area.

Another existing approach uses an additional control signal (not the scan reset signal) from a dedicated pad ORed with the combinational logic at the end of each reset path. The additional control signal controls reset propagation during test captures where the scan reset is not pulsed.

However, this solution has significant limitations. The approach only prevents glitches for the first stage of combinational logic, with glitches still possible in subsequent stages. Additional control signals and corresponding pads are needed for each stage to handle multiple pipeline stages. Each additional pad reduces test parallelism and increases test time. Furthermore, since the scan reset and the additional control signals cannot be pulsed during the same capture cycle, this restricts certain test scenarios, reducing overall test coverage and increasing test time.

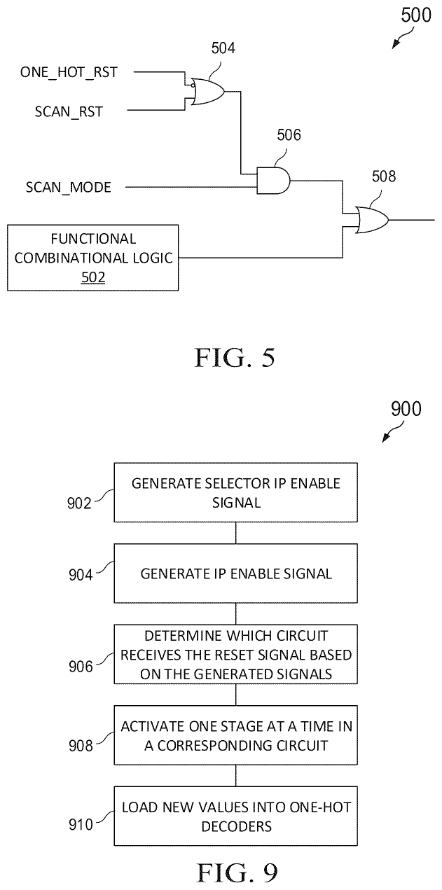

FIG. 5 illustrates a schematic of an embodiment reset generation logic circuit 500, which forms a component implemented in the reset generation circuit 102, reset select logic circuit 104, and each IP block 106 of a system-on-chip (SoC) reset architecture. The circuit includes functional combinational logic 502 and a series of logic gates that control reset signal distribution. The circuit comprises a first OR gate 504, an AND gate 506, and a second OR gate 508, which may (or may not) be arranged as shown. The reset generation logic circuit 500 may include additional components that are not shown.

The reset generation logic circuit 500 receives several input signals: an active-high one-hot decoder reset (ONE_HOT_RST) signal, a scan reset (SCAN_RST) signal, and a scan mode (SCAN_MODE) control signal. The first OR gate 504 combines the one-hot decoder reset signal—after an inverter operation—and the scan reset signal. The output of the first OR gate 504 feeds into the AND gate 506 along with the scan mode control signal. The second OR gate 508 receives the output from the AND gate 506 and the output from the functional combinational logic 502.

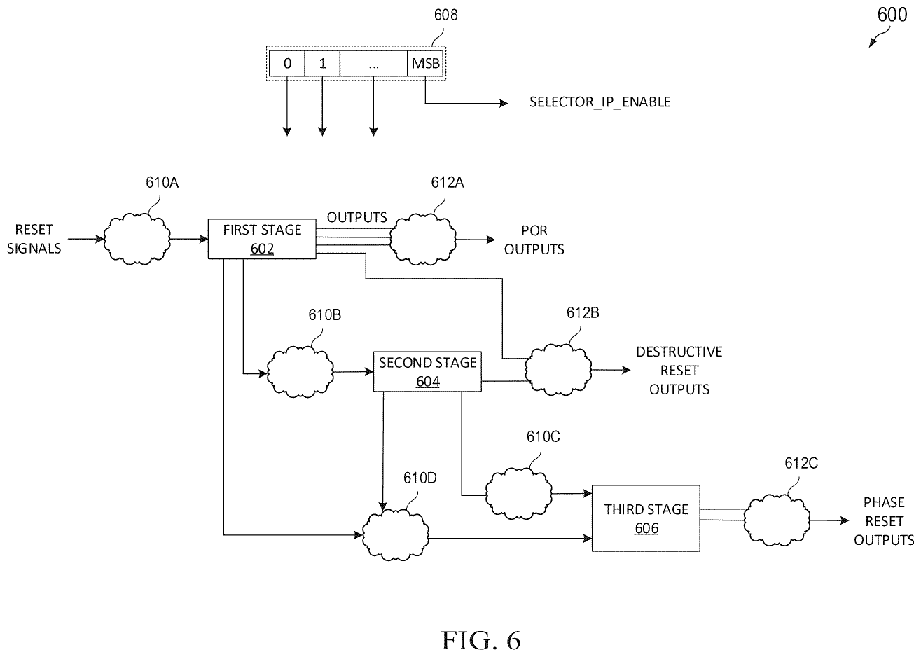

In embodiments, the reset generation circuit 102, reset select logic circuit 104, and each IP block 106 include a corresponding one-hot decoder, as further detailed in FIGS. 6, 7, and 8. The one-hot decoders are part of their respective scan chains and are loaded with test values during the shift phase (i.e., before Time T₀ when the scan enable signal is ‘1’, as shown in FIG. 3). At the end of the shift phase, the loaded values in the one-hot decoders remain stable and unchanged during the capture phase. New values are loaded into the one-hot decoders during the next shift phase (i.e., after time T₁ when the scan enable signal transitions back to ‘1’).

During scan mode operation, when the scan enable and scan reset signals are ‘1’, there are no resets in the system. When the scan enable and the scan reset signals transition to ‘0’, the one-hot decoder controls reset distribution.

The one-hot decoder's most significant bit (MSB) in the reset generation circuit 102 serves as a one-hot decoder reset signal for the reset generation logic circuits within the reset select logic circuit 104 and IP blocks 106. When the scan reset signal transitions from ‘1’ to ‘0’, the MSB of the one-hot decoder in the reset generation circuit 102 is ‘0’, and reset control is confined to within the reset generation circuit 102.

When the most significant bit of the reset generation circuit's one-hot decoder is ‘0’, the one-hot decoder reset signal for the reset select logic circuit 104 and each IP block 106 is ‘0’. In this case, during scan mode, the ‘0’ one-hot decoder reset signal is inverted to ‘1’ at the input of the first OR gate 504, so the first OR gate 504 outputs ‘1’. Since the scan mode signal is also ‘1’, both inputs to the AND gate 506 are ‘1’, causing the AND gate 506 to output ‘1’. This prevents any reset from occurring in the reset select logic circuit 104 and IP blocks 106.

During functional mode operation, when the scan mode control signal is at logic low, the AND gate 506 outputs a ‘0’ value to the first input of the second OR gate 508. Since one input of the OR gate 508 is ‘0’, its output directly follows the value from its other input—the functional combinational logic 502. This ensures that during functional mode, the reset generation logic circuit 500 passes through the functional combinational logic output unmodified.

This arrangement allows the circuit to selectively control reset propagation based on whether the system is in functional or test mode. The reset signals propagate during functional operation through the functional combinational logic 502. During test mode, the one-hot decoder values control reset distribution while preventing unwanted glitch propagation.

In embodiments, the specific logic gates shown in FIG. 5 serve as an example implementation. The logic gate types, arrangements, and combinations may vary while maintaining the same functional relationships between the signals to achieve the desired reset control behavior.

The reset generation logic circuit 500, when employed within the reset generation logic circuit 100, provides glitch-free full coverage by controlling the reset operation and observing one stage of multiple stages at a time. By implementing this circuit throughout the reset distribution network and combining it with one-hot decoders in each domain, the architecture achieves complete reset path testing without the drawbacks of conventional methods. This arrangement allows the circuit to selectively control reset propagation based on whether the system is in functional or test mode. The reset signals propagate during functional operation through the functional combinational logic 502. During test mode, the one-hot decoder values control reset distribution while preventing unwanted glitch propagation.

FIG. 6 illustrates a block diagram of an embodiment reset generation circuit 600, which can be implemented as the reset generation circuit 102 of FIG. 1. The reset generation circuit 600 includes a first stage 602, a second stage 604, a third stage 606, a one-hot decoder 608, reset generation logic circuits 610A-D, and logic circuits 612A-C, which may (or may not) be arranged as shown. Reset generation circuit 600 may include additional components not shown, such as additional stages.

The stages represent sequential reset processing blocks that handle different types of reset signals. Each stage is coupled to an associated reset generation logic circuit 610.

Each reset generation logic circuit 610A-D implements the reset generation logic circuit 500 shown in FIG. 5, which includes the functional combinational logic 502 as part of the circuit. The reset generation logic circuits 610A-D control how reset signals propagate within and between stages.

The logic circuits 612A-C correspond to the functional combinational logic 502 shown in FIG. 5. These logic circuits are coupled to outputs of driver circuits (i.e., driver blocks) and are not coupled to the reset of any flip-flops present within the stages. Test glue is added in the driver circuits after the logic circuits 612A-C that are present within that path, before reaching the reset of any flip-flops present within the stage of a next circuit.

The three-stage architecture shown in FIG. 6 is non-limiting, and in other embodiments, fewer or greater stages are contemplated based on system requirements.

In embodiments, reset signals to the first stage 602 originate from, for example, a Power Management Controller Digital (PMCDIG) circuit that multiplexes various analog reset sources, such as power-on-reset signals, monitor outputs, and threshold detector signals, with the scan reset signal during test mode. These signals pass through reset generation logic circuit 610A before entering the first stage 602.

The first stage 602 is configured to process the initial reset signals and generate power-on-reset (POR) outputs provided to the reset select logic circuit 104 through logic circuit 612A. The logic circuit 612A is coupled to the reset generation logic circuit 708A of the first circuit logic 701 in the reset select logic circuit 700.

The second stage 604 receives inputs from the first stage 602 through reset generation logic circuit 610B. The logic circuit 612B generates destructive reset outputs through logic circuit 612B and the output of the first stage 602. The logic circuit 612B generates destructive reset outputs and is coupled to the reset generation logic circuit 708A of the second circuit logic 703 in the reset select logic circuit 700.

The third stage 606 receives inputs from the first stage 602 and second stage 604 through reset generation logic circuit 610D and from the second stage 604 through reset generation logic circuit 610C, and generates phase reset outputs through logic circuit 612C. The logic circuit 612C is coupled to reset generation logic circuit 708A of the third circuit logic 705 in the reset select logic circuit 700.

It should be appreciated that in some embodiments, the reset flip-flops of a stage (e.g., the third stage 606) are controllable from the output signals of multiple stages (e.g., the first stage 602 and the second stage 604) that pass through a second OR gate 508. In some embodiments, however, the reset flip-flops of the stage are controllable from the output signals of a single stage (e.g., the second stage 604) that pass through a second OR gate 508.

The one-hot decoder 608 controls the reset distribution locally within the reset generation circuit 600 and externally with the reset select logic circuit 104 and the IP blocks 106 through the selector IP enable (SELECTOR_IP_ENABLE) signal. In embodiments, the selector IP enable signal is set by the most significant bit of the one-hot decoder 608. The reset control locally within the reset generation circuit 600 is set by one or more bit combinations of the one-hot decoder 608.

In a non-limiting example, if the one-hot decoder 608 has three bits, ‘001’ resets the first stage 602, ‘010’ resets the second stage 604, and ‘100’ resets the third stage 606—these are examples of one-hot encoding patterns where only one bit is set to ‘1’ at a time. The most significant bit has a value of ‘0’ in each case, indicating that resets are contained within the reset generation circuit 600.

In embodiments, the number of bits in the one-hot decoder 608 is configurable and can be based on the number of stages in the reset generation circuit 600. In embodiments, for a reset generation circuit with N stages, the one-hot decoder includes at least log₂(N)+1 bits, where log₂(N) bits are needed to identify each stage uniquely, and the extra bit (typically the MSB) serves as the selector IP enable signal. For example, a circuit with 3-4 stages would need 2 bits to identify each stage plus one bit for the selector IP enable, for a total of three bits. A circuit with 5-8 stages would need three bits to identify each stage plus one bit for the selector IP enable, for a total of four bits.

As only one stage is reset at a time, based on the value of the one-hot decoder 608, no glitch is propagated—either through the reset generation circuit 600, the reset select logic circuit 104, or the IP blocks 106.

When the scan enable signal transitions to ‘0’ and the scan reset signal transitions from ‘1’ to ‘0’, the one-hot decoder 608 controls which stage receives a reset signal. At the end of the shift phase, when the MSB is set to ‘1’, resets are prevented from occurring within the reset generation circuit 600, allowing resets to propagate to either the reset select logic circuit 104 or IP block 106, depending on additional control signals.

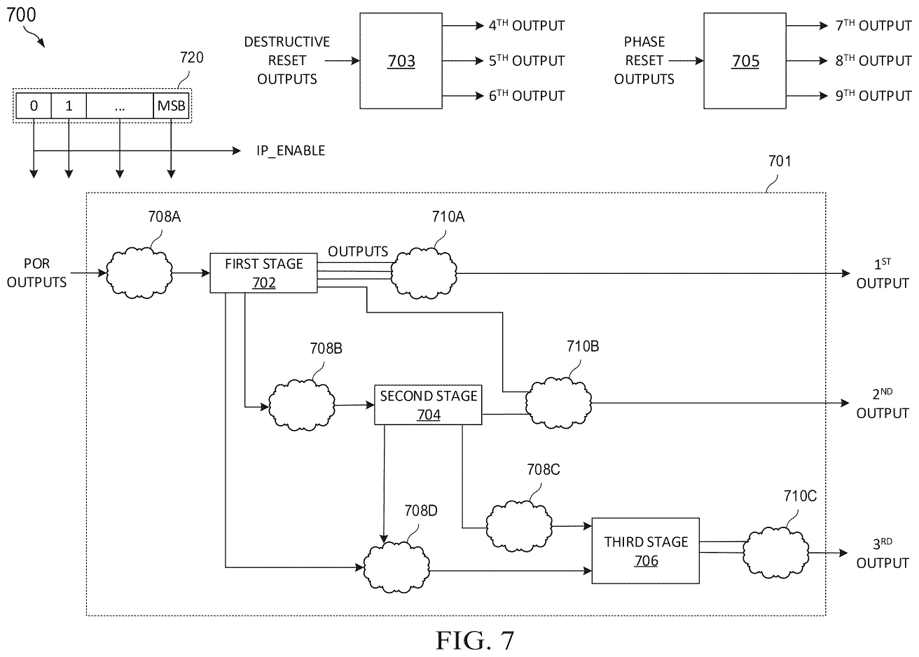

FIG. 7 illustrates a block diagram of an embodiment reset select logic circuit 700, which can be implemented as the reset select logic circuit 104 of FIG. 1. The reset select logic circuit 700 includes a first circuit logic 701, a second circuit logic 703, a third circuit logic 705, and a selector one-hot decoder 720. The first circuit logic 701 contains three stages: first stage 702, second stage 704, and third stage 706, along with reset generation logic circuits 708A-D and logic circuits 710A-C. Similarly, the second circuit logic 703 and third circuit logic 705 each contain three internal stages (not shown in detail for clarity). Reset select logic circuit 700 may include additional components not shown.

Each reset generation logic circuit 708A-D implements the reset generation logic circuit 500 shown in FIG. 5, which includes the functional combinational logic 502 as part of its structure. The reset generation logic circuits 708A-D control how reset signals propagate within and between stages. The output logic circuits 710A-C correspond to the functional combinational logic 502 shown in FIG. 5. These logic circuits are coupled to driver circuit outputs and are not coupled to the reset of any flip-flops present within the stages. Test glue addition is done in the driven circuit after the functional combinational logic 502 present within that path.

The reset select logic circuit 700 receives the selector IP enable signal as the most significant bit of the one-hot decoder 608 of the reset generation circuit 600. The reset select logic circuit 700 also receives PoR outputs from the reset generation circuit 600 as inputs to the first circuit logic 701, destructive reset outputs as inputs to the second circuit logic 703, and phase reset outputs as inputs to the third circuit logic 705.

The output logic circuit 710A is coupled to the reset generation logic circuit 810A of the first IP block 106A. The output logic circuit 710B is coupled to reset generation logic circuit 810A of the second IP block 106B. The output logic circuit 710C is coupled to reset generation logic circuit 810A of the third IP block 106C.

In response to the selector IP enable signal being ‘0’, no reset occurs within the reset select logic circuit 700 or any IP block 106. When the selector IP enable signal is ‘1’, a reset can occur within the reset select logic circuit 700, depending on the values in the selector one-hot decoder 720.

In embodiments, the bits of the selector one-hot decoder 720 can be divided into two subsets. A first subset controls the reset condition through the IP enable (IP_ENABLE) signal. It can be used to indicate whether the reset occurs in the reset select logic circuit 700 or one of the IP blocks 106. A second subset determines which specific stage of which circuit logic (e.g., the first circuit logic 701, the second circuit logic 703, or the third circuit logic 705) within the reset select logic circuit 700 receives the reset signal when the IP enable signal indicates that resets are confined to the reset select logic circuit 700.

For example, when the IP enable signal contains all zeros and the selector IP enable signal is ‘1’, resets are limited to the reset select logic circuit 700. In this case, the second subset determines which of the nine stages (three stages in each of the three circuit logics) receives the reset. When the first subset contains any non-zero bit, resets are directed to an IP block 106 rather than the reset select logic circuit 700.

The first circuit logic 701 processes the PoR outputs from the reset generation circuit 600 through its three stages and generates three outputs: 1st output, 2nd output, and 3rd output. The second circuit logic 703 processes destructive reset outputs and generates 4th, 5th, and 6th outputs, while the third circuit logic 705 processes phase reset outputs and generates 7th, 8th, and 9th outputs. Each stage within these circuit logics contains instances of the reset generation logic circuit 500 shown in FIG. 5, implemented as reset generation logic circuits 708A-D and logic circuits 710A-C.

Similar to the reset generation circuit 600, the stages in the reset select logic circuit 700 represent sequential reset processing blocks. The reset generation logic circuits 708A-D control how reset signals propagate within and between stages, while the logic circuits 710A-C control how reset signals propagate to outputs.

In embodiments, the specific number of stages, circuit logics, and bit configurations shown in FIG. 7 are exemplary. The number of bits in the selector one-hot decoder 720 may vary based on system requirements. Similar to the reset generation circuit 600, the selector one-hot decoder 720 may have log₂(N)+M bits, where N is the number of stages within the reset select logic circuit 700 requiring unique identification, and M is the number of bits needed to determine whether resets are confined to the reset select logic circuit 700 or directed to specific IP blocks. The arrangement of stages, reset generation logic circuits, logic circuits, and connections may also vary while maintaining the same functional relationships between components.

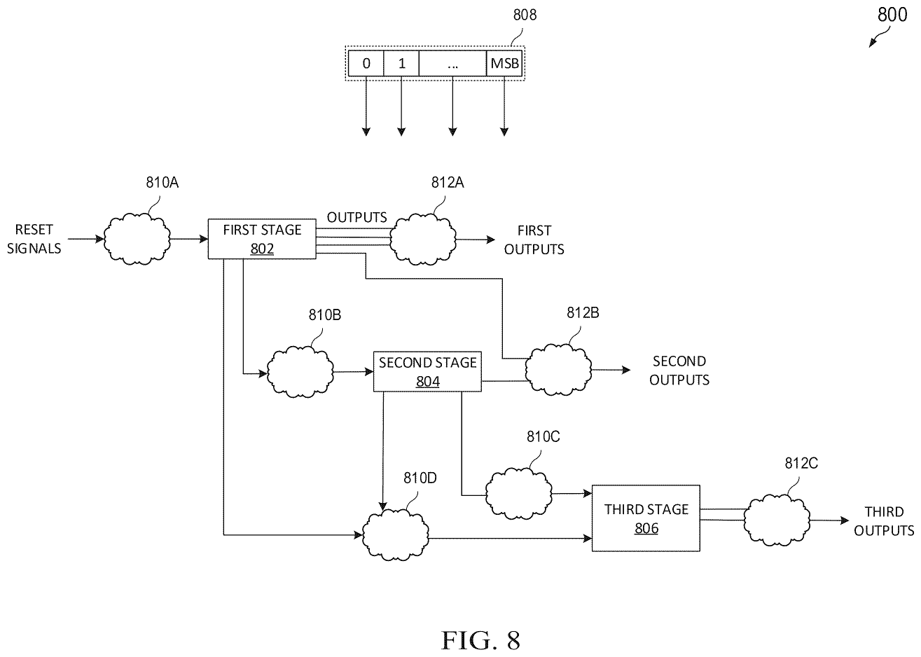

FIG. 8 illustrates a block diagram of an embodiment IP block 800, which can be implemented as one of the IP blocks 106 in FIG. 1. The IP block 800 may represent a low-power boot IP, a debug boot IP, a CPU protocol IP, or other specialized functional blocks. The IP block 800 includes a first stage 802, a second stage 804, a third stage 806, an IP one-hot decoder 808, reset generation logic circuits 810A-D, and logic circuits 812A-C, which may (or may not) be arranged as shown. IP block 800 may include additional components not shown, such as additional stages.

The stages represent sequential reset processing blocks that handle different types of reset signals. Each reset generation logic circuit 810A-D implements the reset generation logic circuit 500 shown in FIG. 5, which includes the functional combinational logic 502 as part of its structure. The reset generation logic circuits 810A-D control how reset signals propagate within and between stages.

The output logic circuits 812A-C correspond to the functional combinational logic 502 shown in FIG. 5. These logic circuits are coupled to driver circuit outputs and are not coupled to the reset of any flip-flops present within the stages. Test glue is added in the drive circuits after the functional combinational logic 502 is present within that path.

The three-stage architecture shown in FIG. 8 is non-limiting, and in other embodiments, fewer or greater stages are contemplated based on system requirements.

In embodiments, reset signals to the first stage 802 originate from one of the outputs of the reset select logic circuit 700, such as from one of the first circuit logic 701, the second circuit logic 703, or the third circuit logic 705. These signals pass through reset generation logic circuit 810A before entering the first stage 802.

The first stage 802 processes the reset signals and generates first outputs through logic circuit 812A. The second stage 804 receives inputs from the first stage 802 through reset generation logic circuit 810B and generates second outputs through logic circuit 812B. The third stage 806 receives inputs from both the first stage 802 through reset generation logic circuit 810D and from the second stage 804 through reset generation logic circuit 810C, and generates third outputs through logic circuit 812C.

The IP one-hot decoder 808 controls the reset distribution locally within the IP block 800. Unlike the one-hot decoder 608 in the reset generation circuit 600, the IP one-hot decoder 808 does not provide signals to other circuits outside the IP block 800. Instead, it works in combination with the selector IP enable signal from the reset generation circuit 600 and the IP enable signal from the reset select logic circuit 700 to determine when and which specific stage within the IP block 800 receives a reset signal.

In a non-limiting example, if the IP one-hot decoder 808 has three bits, ‘001’ resets the first stage 802, ‘010’ resets the second stage 804, and ‘100’ resets the third stage 806—these are examples of one-hot encoding patterns where only one bit is set to ‘1’ at a time. The IP block 800 will process these reset signals when the selector IP enable signal from the reset generation circuit 600 and the IP enable signal from the reset select logic circuit 700 are set to ‘1’.

In embodiments, the number of bits in the IP one-hot decoder 808 is configurable and can be based on the number of stages in the IP block 800. For an IP block with N stages, the IP one-hot decoder may include log₂(N) bits, where log₂(N) bits identify each stage uniquely.

As only one stage is reset at a time, based on the value of the IP one-hot decoder 808, no glitch is propagated through the IP block 800. This controlled reset distribution ensures reliable system initialization and operation during both functional and test modes.

In embodiments, the specific number of stages and bit configurations shown in FIG. 8 are exemplary. The arrangement of stages, reset generation logic circuits, logic circuits, and connections may vary while maintaining the same functional relationships between components.

Embodiments of the disclosure provide several advantages over conventional reset testing approaches. The architecture eliminates scan reset multiplexers throughout the device. This streamlined approach reduces circuit complexity while maintaining full test coverage.

The one-hot decoders are integrated within the scan chains and reset with power-on-reset signals. Within the reset generation circuit, reset select logic circuit, and IP blocks, internal reset logic directly control flip-flop reset/set operations based on the respective one-hot decoder values. This direct control eliminates the need for intermediate multiplexers at each pipeline stage.

Removing multiplexers from the functional reset paths reduces delay by eliminating one AND gate delay from the functional combinational logic to the reset/set pins of flip-flops. This improves timing performance during normal operation while still providing complete stuck-at-fault coverage of internal reset paths without introducing glitches.

The architecture does not require additional observability logic, such as observation flip-flops or converting non-resettable flip-flops to resettable versions. This avoids increasing test time by adding more flip-flops to scan chains and eliminates the need for additional timing checks. The overall result is an optimized area cost for reset testing while achieving comprehensive test coverage.

Unlike conventional approaches that struggle with glitch propagation, the disclosed architecture fully covers internal reset paths without introducing unwanted glitches. This is accomplished through the hierarchical control provided by the one-hot decoders, which activate only one reset stage at a time, preventing timing-related glitches that can corrupt test results.

The architecture uses the scan reset pad as the internal reset control signal, eliminating the need for additional dedicated control pads. This avoids reducing test parallelism, saving test time, and reducing overall test cost. Previous solutions often required multiple control signals for different pipeline stages, increasing complexity and test time.

FIG. 9 illustrates a flowchart of an embodiment method 900 for controlling reset distribution in a system-on-chip (SoC). Method 900 provides a reset testing approach that maintains signal integrity throughout the reset distribution network while achieving complete test coverage. By controlling reset propagation through hierarchical one-hot decoders, the method prevents unwanted glitches in conventional reset testing approaches.

At step 902, a selector IP enable signal is generated corresponding to a most significant bit of a first one-hot decoder in a reset generation circuit. This signal serves as the primary control mechanism for determining whether resets propagate beyond the reset generation circuit.

At step 904, an IP enable signal is generated by a second one-hot decoder in a reset select logic circuit. This signal works in conjunction with the selector IP enable signal to further refine reset distribution control.

At step 906, the method determines which circuit among the reset generation circuit, the reset select logic circuit, and a plurality of intellectual property (IP) blocks receives a reset signal. This determination may be based on the selector IP enable signal and the IP enable signal.

In embodiments, when the selector IP enable signal is at a first logic level (e.g., logic low or ‘0’), reset can be confined to the reset generation circuit. When the selector IP enable signal is at a second logic level (e.g., logic high or ‘1’) and the IP enable signal is at the first logic level, reset can be confined to the reset select logic circuit. When both the selector IP enable signal and the IP enable signal are at the second logic level, reset can be directed to one of the IP blocks.

At step 908, reset is activated one stage at a time within the determined circuit based on values in a respective one-hot decoder to prevent glitch propagation. This selective activation ensures that reset signals do not create unwanted glitches that could corrupt test results or cause improper system initialization.

In embodiments, stable values are maintained in the first, second, and third one-hot decoders during a capture phase when a scan enable signal is at a first logic level. This stability ensures consistent reset control during the critical capture phase of testing.

At step 910, new values are loaded into the first, second, and third one-hot decoders during a shift phase when the scan enable signal is at a second logic level. This allows for reconfiguration of the reset distribution for subsequent test cycles.

It is noted that all steps outlined in the method are not necessarily required and can be optional. Further, changes to the arrangement of the steps, removal of one or more steps and path connections, and addition of steps and path connections are similarly contemplated.

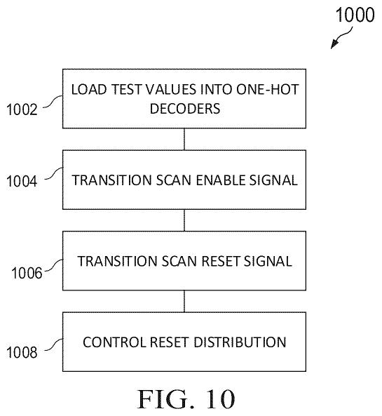

FIG. 10 illustrates a flowchart of an embodiment method 1000 for design for testability (DFT) in a system-on-chip (SoC). Method 1000 provides a reset testing approach that maintains signal integrity throughout the reset distribution network while achieving complete test coverage. By controlling reset propagation through hierarchical one-hot decoders, the method prevents unwanted glitches in conventional reset testing approaches.

At step 1002, test values are loaded into one-hot decoders within a reset generation circuit, a reset select logic circuit, and a plurality of intellectual property (IP) blocks during a shift phase in response to a scan enable signal being at a first logic level.

The reset generation circuit can be configured to generate reset signals, the reset select logic circuit can be configured to route reset signals, and each IP block can be configured to perform dedicated processing operations within the system-on-chip.

In embodiments, analog reset sources can be multiplexed with the scan reset signal at a power management controller digital circuit that provides reset signals to the reset generation circuit. This multiplexing allows for testing of both functional and test reset paths.

At step 1004, the scan enable signal transitions to a second logic level to begin a capture phase. This transition marks the end of the shift phase and prepares the system for capturing test responses.

In embodiments, stable values can be maintained in the one-hot decoders during this capture phase to ensure controlled reset activation without glitch propagation between stages.

At step 1006, a scan reset signal can transition from the first logic level to the second logic level during the capture phase. This transition triggers reset operations according to the values loaded in the one-hot decoders.

In embodiments, the reset generation circuit can generate power-on-reset outputs, destructive reset outputs, and phase reset outputs in response to this transition, and the reset select logic circuit can route these outputs to specific IP blocks based on values in the one-hot decoders.

At step 1008, reset distribution can be controlled based on values in the one-hot decoders to prevent glitch propagation by activating reset in only one stage at a time. This selective activation ensures that reset signals do not create unwanted glitches that could corrupt test results.

In embodiments, controlling reset distribution can include determining, based on a most significant bit of a first one-hot decoder in the reset generation circuit, whether reset is confined to the reset generation circuit or can propagate to the reset select logic circuit or the IP blocks. In response to the most significant bit being at the second logic level, reset can be confined to the reset generation circuit, and in response to the most significant bit being at the first logic level, reset can propagate to the reset select logic circuit or the IP blocks. Additionally, bits of a second one-hot decoder in the reset select logic circuit can determine whether reset occurs in the reset select logic circuit or is passed to the IP blocks.

It is noted that all steps outlined in the method are not necessarily required and can be optional. Further, changes to the arrangement of the steps, removal of one or more steps and path connections, and addition of steps and path connections are similarly contemplated.

A fourth aspect relates to a method for controlling reset distribution in a system-on-chip (SoC), comprising receiving a selector IP enable signal from a most significant bit of a first one-hot decoder in a reset generation circuit; receiving an IP enable signal from a second one-hot decoder in a reset select logic circuit; determining, based on the selector IP enable signal and the IP enable signal, which circuit among the reset generation circuit, the reset select logic circuit, and a plurality of intellectual property (IP) blocks receives a reset signal; and activating reset in only one stage at a time within the determined circuit based on values in a respective one-hot decoder to prevent glitch propagation.

In a first implementation form of the method, according to the fourth aspect as such, in response to the selector IP enable signal being at a first logic level, reset is confined to the reset generation circuit, wherein in response to the selector IP enable signal being at a second logic level and the IP enable signal being at the first logic level, reset is confined to the reset select logic circuit, and wherein in response to the selector IP enable signal and the IP enable signal being at the second logic level, reset is directed to one of the IP blocks.

In a second implementation form of the method, according to the fourth aspect as such or any preceding implementation form of the first aspect, the method further comprises maintaining stable values in the first, second, and third one-hot decoders during a capture phase in response to the scan enable signal being at a first logic level; and loading new values into the first, second, and third one-hot decoders during a shift phase in response to the scan enable signal being at a second logic level.

A first aspect relates to a reset testing system, comprising a reset generation circuit including a first one-hot decoder, the reset generation circuit configured to generate and manage reset signals during functional and test operations; a reset select logic circuit coupled to the reset generation circuit and including a second one-hot decoder, the reset select logic circuit configured to route reset signals to different intellectual property (IP) blocks; and a plurality of intellectual property (IP) blocks coupled to the reset select logic circuit, each IP block including a third one-hot decoder and configured to perform dedicated processing operations within a system-on-chip, wherein each of the first one-hot decoder, the second one-hot decoder, and the third one-hot decoder is configured to control reset distribution within their respective circuits during test mode to prevent glitch propagation by activating reset in only one stage at a time.

In a first implementation form of the reset testing system, according to the first aspect as such, the first one-hot decoder includes a most significant bit that provides a selector IP enable signal to the reset select logic circuit.

In a second implementation form of the reset testing system, according to the first aspect as such or any preceding implementation form of the first aspect, in response to the selector IP enable signal being at a first logic level, reset is confined to the reset generation circuit, and in response to the selector IP enable signal being at a second logic level, reset can propagate to the reset select logic circuit or the IP blocks.

In a third implementation form of the reset testing system, according to the first aspect as such or any preceding implementation form of the first aspect, the second one-hot decoder includes bits divided into a first subset that controls whether reset occurs in the reset select logic circuit or is passed to the IP blocks, and a second subset that determines which stage within the reset select logic circuit receives a reset signal.

In a fourth implementation form of the reset testing system, according to the first aspect as such or any preceding implementation form of the first aspect, each of the first one-hot decoder, the second one-hot decoder, and the third one-hot decoder is part of a respective scan chain and is loaded with test values during a shift phase in response to a scan enable signal being at a first logic level.

In a fifth implementation form of the reset testing system, according to the first aspect as such or any preceding implementation form of the first aspect, the loaded values in the one-hot decoders remain stable during a capture phase in response to the scan enable signal transitioning to a second logic level.

In a sixth implementation form of the reset testing system, according to the first aspect as such or any preceding implementation form of the first aspect, the reset generation circuit comprises a first stage coupled to receive reset signals from a power management controller digital circuit; a second stage coupled to the first stage; and a third stage coupled to the first stage and the second stage, wherein the first one-hot decoder controls which of the first stage, the second stage, or the third stage receives a reset signal during test mode.

A second aspect relates to a reset generation logic circuit, comprising a functional combinational logic circuit configured to process reset signals during functional operation; a first OR gate having a first input coupled to receive a one-hot decoder reset signal and a second input coupled to receive a scan reset signal; an AND gate having a first input coupled to an output of the first OR gate and a second input coupled to receive a scan mode control signal; and a second OR gate having a first input coupled to an output of the AND gate and a second input coupled to an output of the functional combinational logic circuit, the second OR gate configured to selectively output either the functional reset signal or the test reset signal based on the scan mode control signal, wherein the one-hot decoder reset signal is derived from a one-hot decoder that controls reset distribution to prevent glitch propagation by activating reset in only one stage at a time.

In a first implementation form of the reset generation logic circuit, according to the second aspect as such, during functional mode operation, in response to the scan mode control signal being at a first logic level, an output of the second OR gate follows the output of the functional combinational logic circuit.

In a second implementation form of the reset generation logic circuit, according to the second aspect as such or any preceding implementation form of the second aspect, the one-hot decoder reset signal is active in response to a scan reset signal transitioning from a first logic level to a second logic level and a scan enable signal being at the second logic level.

In a third implementation form of the reset generation logic circuit, according to the second aspect as such or any preceding implementation form of the second aspect, the one-hot decoder is part of a scan chain and is loaded with test values during a shift phase in response to a scan enable signal being at a first logic level.

In a fourth implementation form of the reset generation logic circuit, according to the second aspect as such or any preceding implementation form of the second aspect, the loaded values in the one-hot decoder remain stable during a capture phase in response to the scan enable signal transitioning to a second logic level.

In a fifth implementation form of the reset generation logic circuit, according to the second aspect as such or any preceding implementation form of the second aspect, the one-hot decoder is implemented in a reset generation circuit configured to generate and manage reset signals during functional and test operations, a reset select logic circuit configured to route reset signals to different intellectual property blocks, and an intellectual property (IP) block configured to perform dedicated processing operations within a system-on-chip.

In a sixth implementation form of the reset generation logic circuit, according to the second aspect as such or any preceding implementation form of the second aspect, the one-hot decoder is configured to control reset distribution in a hierarchical reset architecture comprising a reset generation circuit, a reset select logic circuit, and a plurality of intellectual property (IP) blocks; and prevent glitch propagation between pipeline stages by activating reset in one stage based on values loaded into the one-hot decoder during a shift phase.

A third aspect relates to a method for design for testability (DFT) in a system-on-chip (SoC), the method comprising loading test values into one-hot decoders within a reset generation circuit, a reset select logic circuit, and a plurality of intellectual property (IP) blocks during a shift phase in response to a scan enable signal being at a first logic level, wherein the reset generation circuit is configured to generate reset signals, the reset select logic circuit is configured to route reset signals, and each IP block is configured to perform dedicated processing operations within the system-on-chip; transitioning the scan enable signal to a second logic level to begin a capture phase; transitioning a scan reset signal from the first logic level to the second logic level during the capture phase; and controlling reset distribution based on values in the one-hot decoders to prevent glitch propagation by activating reset in only one stage at a time.

In a first implementation form of the method, according to the third aspect as such, controlling reset distribution comprises determining, based on a most significant bit of a first one-hot decoder in the reset generation circuit, whether reset is confined to the reset generation circuit or can propagate to the reset select logic circuit or the IP blocks.

In a second implementation form of the method, according to the third aspect as such or any preceding implementation form of the third aspect, in response to the most significant bit being at the second logic level, reset is confined to the reset generation circuit, and in response to the most significant bit being at the first logic level, reset can propagate to the reset select logic circuit or the IP blocks.

In a third implementation form of the method, according to the third aspect as such or any preceding implementation form of the third aspect, the method further comprising determining, based on bits of a second one-hot decoder in the reset select logic circuit, whether reset occurs in the reset select logic circuit or is passed to the IP blocks.

In a fourth implementation form of the method, according to the third aspect as such or any preceding implementation form of the third aspect, the method further comprising multiplexing analog reset sources with the scan reset signal at a power management controller digital circuit that provides reset signals to the reset generation circuit.

In a fifth implementation form of the method, according to the third aspect as such or any preceding implementation form of the third aspect, the method further comprising generating, by the reset generation circuit, power-on-reset outputs, destructive reset outputs, and phase reset outputs; routing, by the reset select logic circuit, the power-on-reset outputs, destructive reset outputs, and phase reset outputs to specific IP blocks based on values in the one-hot decoders; and maintaining stable values in the one-hot decoders during the capture phase to ensure controlled reset activation without glitch propagation between stages.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A reset testing system, comprising:
a reset generation circuit including a first one-hot decoder, the reset generation circuit configured to generate and manage reset signals during functional and test operations;
a reset select logic circuit coupled to the reset generation circuit and including a second one-hot decoder, the reset select logic circuit configured to route reset signals to different intellectual property (IP) blocks; and
a plurality of intellectual property (IP) blocks coupled to the reset select logic circuit, each IP block including a third one-hot decoder and configured to perform dedicated processing operations within a system-on-chip,
wherein each of the first one-hot decoder, the second one-hot decoder, and the third one-hot decoder is configured to control reset distribution within their respective circuits during test mode to prevent glitch propagation by activating reset in only one stage at a time.

2. The reset testing system of claim 1, wherein the first one-hot decoder includes a most significant bit that provides a selector IP enable signal to the reset select logic circuit.

3. The reset testing system of claim 2, wherein in response to the selector IP enable signal being at a first logic level, reset is confined to the reset generation circuit, and in response to the selector IP enable signal being at a second logic level, the reset propagates to the reset select logic circuit or the IP blocks.

4. The reset testing system of claim 1, wherein the second one-hot decoder includes bits divided into a first subset that controls whether reset occurs in the reset select logic circuit or is passed to the IP blocks, and a second subset that determines which stage within the reset select logic circuit receives a reset signal.

5. The reset testing system of claim 1, wherein each of the first one-hot decoder, the second one-hot decoder, and the third one-hot decoder is part of a respective scan chain and is loaded with test values during a shift phase in response to a scan enable signal being at a first logic level.

6. The reset testing system of claim 5, wherein the loaded values in the one-hot decoders remain stable during a capture phase in response to the scan enable signal transitioning to a second logic level.

7. The reset testing system of claim 1, wherein the reset generation circuit comprises:
a first stage coupled to receive reset signals;
a second stage coupled to the first stage; and
a third stage coupled to the first stage and the second stage,
wherein the first one-hot decoder controls which of the first stage, the second stage, or the third stage receives a reset signal during test mode.

8. A reset generation logic circuit, comprising:
a functional combinational logic circuit configured to process reset signals during functional operation;
a first OR gate having a first input coupled to receive a one-hot decoder reset signal and a second input coupled to receive a scan reset signal;
an AND gate having a first input coupled to an output of the first OR gate and a second input coupled to receive a scan mode control signal; and
a second OR gate having a first input coupled to an output of the AND gate and a second input coupled to an output of the functional combinational logic circuit, the second OR gate configured to selectively output the functional reset signal or the test reset signal based on the scan mode control signal,
wherein the one-hot decoder reset signal is derived from a one-hot decoder that controls reset distribution to prevent glitch propagation by activating reset in one stage at a time.

9. The reset generation logic circuit of claim 8, wherein, during functional mode operation, in response to the scan mode control signal being at a first logic level, an output of the second OR gate follows the output of the functional combinational logic circuit.

10. The reset generation logic circuit of claim 8, wherein the one-hot decoder reset signal is active in response to a scan reset signal transitioning from a first logic level to a second logic level and a scan enable signal being at the second logic level.

11. The reset generation logic circuit of claim 8, wherein the one-hot decoder is part of a scan chain and is loaded with test values during a shift phase in response to a scan enable signal being at a first logic level.

12. The reset generation logic circuit of claim 11, wherein the loaded values in the one-hot decoder remain stable during a capture phase in response to the scan enable signal transitioning to a second logic level.

13. The reset generation logic circuit of claim 8, wherein the one-hot decoder is implemented in a reset generation circuit configured to generate and manage reset signals during functional and test operations, a reset select logic circuit configured to route reset signals to different intellectual property blocks, and an intellectual property (IP) block configured to perform dedicated processing operations within a system-on-chip.

14. The reset generation logic circuit of claim 8, wherein the one-hot decoder is configured to:
control reset distribution in a hierarchical reset architecture comprising a reset generation circuit, a reset select logic circuit, and a plurality of intellectual property (IP) blocks; and
prevent glitch propagation between pipeline stages by activating reset in one stage based on values loaded into the one-hot decoder during a shift phase.

15. A method for design for testability (DFT) in a system-on-chip (SoC), the method comprising:
loading test values into one-hot decoders within a reset generation circuit, a reset select logic circuit, and a plurality of intellectual property (IP) blocks during a shift phase in response to a scan enable signal being at a first logic level, wherein the reset generation circuit is configured to generate reset signals, the reset select logic circuit is configured to route reset signals, and each IP block is configured to perform dedicated processing operations within the system-on-chip;
transitioning the scan enable signal to a second logic level to begin a capture phase;
transitioning a scan reset signal from the first logic level to the second logic level during the capture phase; and
controlling reset distribution based on values in the one-hot decoders to prevent glitch propagation by activating reset in one stage at a time.

16. The method of claim 15, wherein controlling reset distribution comprises determining, based on a most significant bit of a first one-hot decoder in the reset generation circuit, whether reset is confined to the reset generation circuit or propagates to the reset select logic circuit or the IP blocks.

17. The method of claim 16, wherein in response to the most significant bit being at the second logic level, reset is confined to the reset generation circuit, and in response to the most significant bit being at the first logic level, the reset propagates to the reset select logic circuit or the IP blocks.

18. The method of claim 15, further comprising determining, based on bits of a second one-hot decoder in the reset select logic circuit, whether reset occurs in the reset select logic circuit or is passed to the IP blocks.

19. The method of claim 15, further comprising multiplexing analog reset sources with the scan reset signal at a power management controller digital circuit that provides reset signals to the reset generation circuit.

20. The method of claim 15, further comprising:
generating, by the reset generation circuit, power-on-reset outputs, destructive reset outputs, and phase reset outputs;
routing, by the reset select logic circuit, the power-on-reset outputs, destructive reset outputs, and phase reset outputs to specific IP blocks based on values in the one-hot decoders; and
maintaining stable values in the one-hot decoders during the capture phase to ensure controlled reset activation without glitch propagation between stages.
